(19) United States
(12) Patent Application Publication
(10) Pub. No.: US 2024/0120449 A1
(43) Pub. Date: Apr. 11, 2024

(54) LIGHT EMITTING DEVICE AND DISPLAY DEVICE

(71) Applicant: SONY SEMICONDUCTOR SOLUTIONS CORPORATION, KANAGAWA (JP)

(72) Inventors: IPPEI NISHINAKA, KANAGAWA (JP); HIROKI NAITO, KANAGAWA (JP); KATSUHIRO TOMODA, KANAGAWA (JP)

(21) Appl. No.: 18/264,374

(22) PCT Filed: Feb. 16, 2022
(86) PCT No.: PCT/JP2022/006171

§ 371 Date: Aug. 4, 2023

(30) Foreign Application Priority Data
Feb. 18, 2021 (JP) 2021-024385

(51) Int. Cl. H01L 33/56; H01L 27/15; H01L 33/00

(52) U.S. Cl. CPC H01L 33/56; H01L 27/156; H01L 33/0095

(57) ABSTRACT

For example, deterioration in image quality due to end-surface vignetting is suppressed. A light emitting device includes at least two light emitting elements provided on a substrate, and a transparent resin part provided so as to cover the light emitting elements, in which in a sectional view, when the size of the width of the light emitting element positioned at an end part is a (μm), a surface distance between the light emitting element and a surface of the transparent resin part is x (μm), an end surface distance between the light emitting element and an end surface of the transparent resin part closest to the light emitting element is y (μm), and the refractive index of the transparent resin part is λm, an expression (1) below or expressions (2) and (3) below are satisfied.

y<(1.44λm−0.76)×x+(0.08λm−0.04)×a−0.02λm−0.47 (Expression 1)

y<(1.44λm−0.76)×x+(0.08λm−0.04)×a−0.02λm−0.47 (Expression 2)

y<(1.44λm−0.76)×x+(0.15λm−0.08)×a−0.06λm−0.61 (Expression 3)

### TECHNICAL FIELD

The present disclosure relates to a light emitting device and a display device.

### BACKGROUND ART

A display including a plurality of light emitting devices including a light emitting element has been known. For example, a light emitting diode (LED) display including an LED as the light emitting element and including a plurality of packages (also referred to as surface mount devices (SMDs) or the like) of a plurality of LEDs has been known. Technologies of improving the image quality of such an LED display have been disclosed (refer to, for example, Patent Documents 1 and 2 described below).

### CITATION LIST

### Patent Documents

Patent Document 1: Japanese Patent Application Laid-Open No. 2006-109932
Patent Document 2: Japanese Patent Application Laid-Open No. 2013-254651

### SUMMARY OF THE INVENTION

### Problems to be Solved by the Invention

In this field, it is desirable to suppress deterioration in image quality as much as possible.

An object of the present disclosure is to provide a light emitting device and a display device that suppress deterioration in image quality as much as possible.

### Solutions to Problems

The present disclosure includes, for example, a light emitting device including:
at least two light emitting elements provided on a substrate; and
a transparent resin part provided so as to cover the light emitting elements, in which
in a sectional view, when the size of the width of the light emitting element positioned at an end part is a (μm), a surface distance between the light emitting element and a surface of the transparent resin part is x (μm), an end surface distance between the light emitting element and an end surface of the transparent resin part closest to the light emitting element is y (μm), and the refractive index of the transparent resin part is λm, an expression (1) below or expressions (2) and (3) below are satisfied.

y<(1.44λm−0.76)×x+(0.08λm−0.04)×a−0.02λm−0.47 (Expression 1)

y<(1.44λm−0.76)×x+(0.08λm−0.04)×a−0.02λm−0.47 (Expression 2)

y<(1.44λm−0.76)×x+(0.15λm−0.08)×a−0.06λm−0.61 (Expression 3)

The present disclosure may include a display device including the light emitting device described above.

### BRIEF DESCRIPTION OF DRAWINGS

FIGS. 1A and 1B are diagrams referred to when problems to be considered in the present disclosure is described.

FIG. 2 is a diagram referred to when problems to be considered in the present disclosure is described.

FIG. 3 is a diagram illustrating a display device according to an embodiment of the present disclosure.

FIG. 4 is a diagram illustrating a light emitting device according to an embodiment of the present disclosure.

FIG. 5 is a diagram illustrating a section taken along line AA-AA in FIG. 3.

FIG. 6 is a diagram referred to when LED package conditions are described.

FIG. 7 is a diagram referred to when LED package conditions are described.

FIG. 8 is a diagram referred to when LED package conditions are described.

### MODE FOR CARRYING OUT THE INVENTION

Embodiments and the like of the present disclosure will be described below with reference to the drawings. Note that the description will be given in the following order.

### Problems to be Considered in Embodiments

### Embodiment

### Modification Examples

Embodiments and the like described below are preferred specific examples of the present disclosure, and the content of the present disclosure is not limited to these embodiments and the like.

### Problems to be Considered in Present Disclosure

First, problems to be considered in the present disclosure will be described below to facilitate understanding of the present disclosure. In a typical LED display, LED chips of three colors (red, green, and blue) are mounted, and an LED package in which the LED chips are packaged is used. Recently, the pitch and cost of the LED display have been reduced. Accordingly, the size and cost of the LED package included in the LED display have been reduced in accordance with this demand.

With the size reduction of the LED package, there occurs a problem that vignetting of light from an LED chip of a certain color among the LED chips of the three colors occurs at an end surface of the LED package and the quantity of light in the certain color decreases. Such a problem is also referred to as single color vignetting, end-surface vignetting, or the like (referred to as end-surface vignetting as appropriate in the following description).

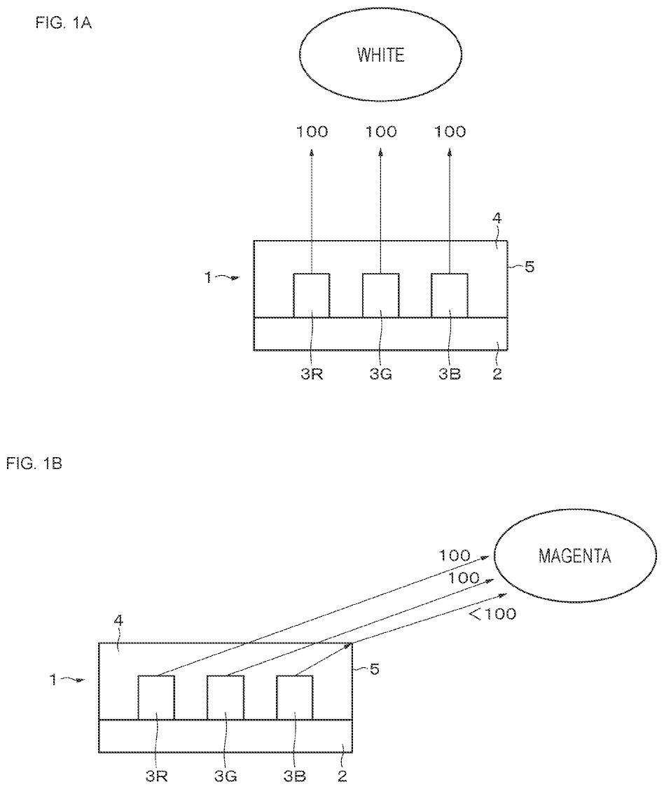

The end-surface vignetting will be described below with reference to FIGS. 1A and 1B. A configuration denoted by reference sign 1 in FIG. 1A is an LED package (LED package 1), and a section of the LED package 1 is illustrated in FIG. 1A. Note that a plurality of LED packages 1 is included in an actual LED display but only one LED package 1 is illustrated for convenience of description.

The LED package 1 includes a substrate 2. Three LED chips, specifically, an LED chip 3R of red, an LED chip 3G of green, and an LED chip 3B of blue are provided on the substrate 2. The LED chip 3R is an example of a first light emitting element configured to emit light in red. The LED chip 3G is an example of a second light emitting element configured to emit light in green. The LED chip 3B is an example of a third light emitting element configured to emit light in blue. Note that the LED chips are referred to as LED chips 3 as appropriate in a case where they do not need to be individually distinguished. Each LED chip 3 is covered (molded) by a transparent resin part 4. The LED package 1 covered by the transparent resin part 4 has a substantially rectangular parallelepiped shape as a whole. When the LED chips 3R, 3G, and 3B emit light as appropriate in accordance with a video signal, the emitted light is visually recognized by a user.

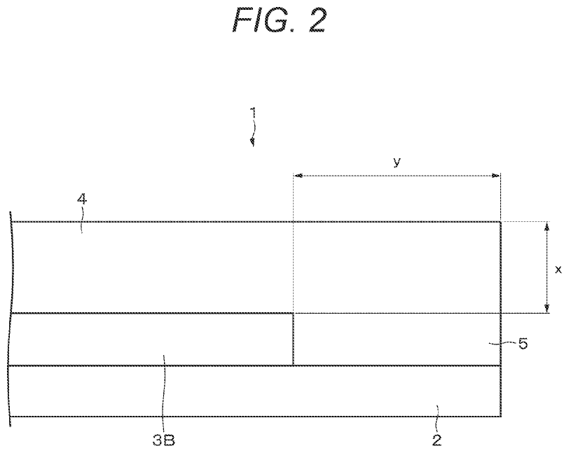

In a case where a plurality of LED chips (of three colors) is incorporated as in the LED package 1, the distances from the respective LED chips to an end surface 5 of the LED package 1 are different. In a typical LED display including RGB light sources, RGB light quantities are adjusted so that luminance when viewed in front aligns to a desired white chromaticity point. The intensities of RGB light quantities are each set to 100. In a case where the LED package 1 is viewed in front as illustrated in FIG. 1A, the light intensities are equal to one another at substantially 100 and thus chromaticity aligns to the white chromaticity point. However, in a case where the LED package 1 is obliquely viewed as illustrated in FIG. 1B, light from an LED chip close to the end surface 5, in other words, the LED chip 3B in the present example is reduced by the end surface 5. Specifically, light quantity at a visual recognition position is reduced due to refraction by the end surface 5. With such end-surface vignetting, the intensity of light quantity of the LED chip 3B becomes lower than 100. Accordingly, as schematically illustrated in FIG. 2, balance among the lights when the LED package 1 is obliquely viewed is lost and shift from the white chromaticity point occurs, and as a result, magenta instead of white is visually recognized due to reduction of blue when the LED package 1 is obliquely viewed, which leads to deterioration in image quality.

FIG. 2 is a diagram illustrating the vicinity of a right end part of the LED package 1 in an enlarged manner. The end-surface vignetting occurs when the relation between x and y in a case where the LED package 1 is placed in air satisfies Expression (1) below, where the refractive index of the transparent resin part 4 is λm, the surface distance between a surface of the LED chip 3B and a surface of the LED package 1 is x, and the end surface distance between an end surface of the LED chip 3B and the end surface 5 of the LED package 1 is y as illustrated in FIG. 2.

ArcTan(y/x)>ArcSin(1/λm) Expression (1)

The end-surface vignetting is more likely to occur through size reduction of the LED package 1. However, the patent documents described above do not consider the end-surface vignetting and are inappropriate as technologies of suppressing deterioration in image quality. For example, in Patent Document 1 described above, a light distribution adjustment layer is formed on a light-emitting surface side to provide a light emitting device having a favorable view angle. However, no consideration is made on the end-surface vignetting, and deterioration in image quality due to the end-surface vignetting occurs. In addition, a display in which a reflection suppression layer is formed on the light-emitting surface to improve contrast is disclosed, but deterioration in image quality due to the end-surface vignetting cannot be suppressed with this configuration, and furthermore, non-negligible decrease of light emission efficiency occurs when the size of an LED package is reduced.

To solve the above-described problems, a light emitting device and a display device that can suppress deterioration in image quality due to the end-surface vignetting will be described below in detail with reference to an embodiment of the present disclosure.

### Embodiment

### Configuration Example of Display Device and Light Emitting Device

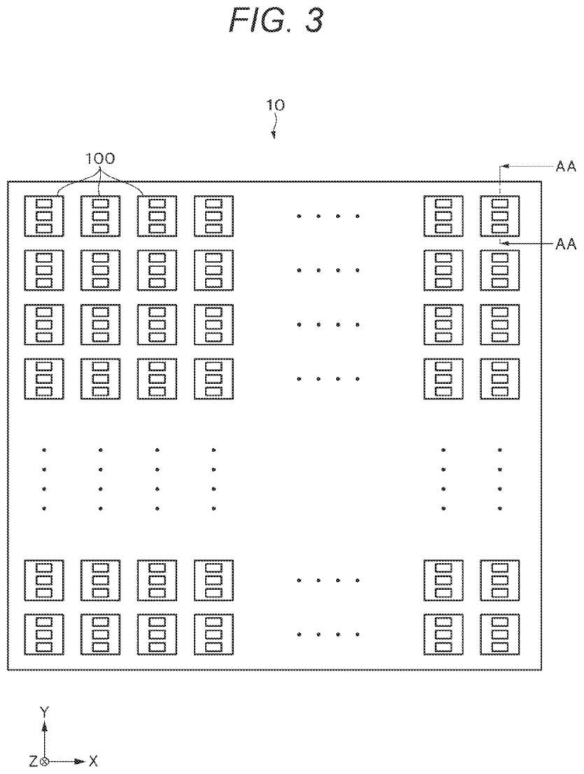

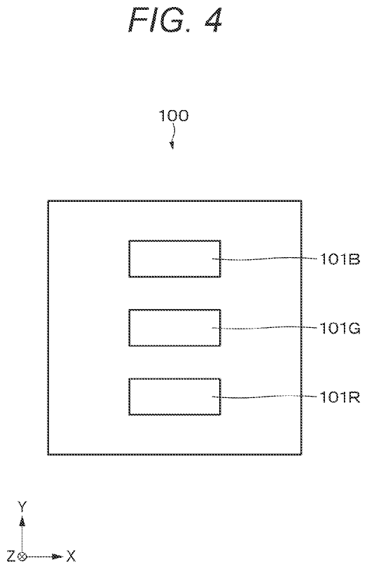

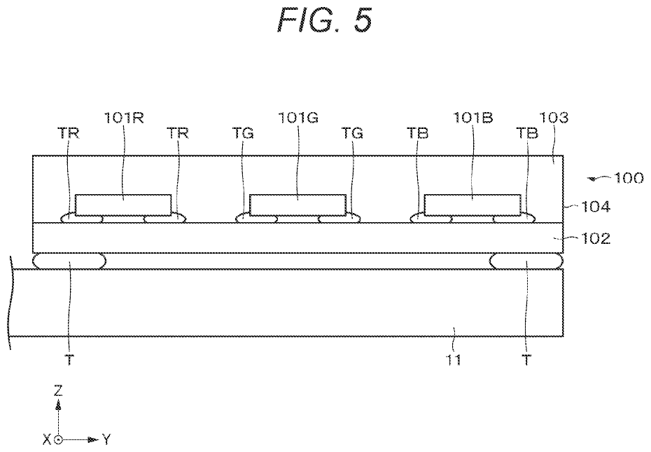

A light emitting device and a display device according to an embodiment of the present disclosure will be described below with reference to FIGS. 3, 4, and 5. FIG. 3 is a front view in which the display device (display device 10) according to the present embodiment is viewed from a display surface. FIG. 4 is a front view in which an LED package 100 that is the light emitting device according to the present embodiment is viewed from the display surface. FIG. 5 is a sectional view of the display device 10 taken along line AA-AA in FIG. 3. Note that, in the following description, the horizontal and vertical directions of the display surface of the display device 10 are referred to as an X axial direction and a Y axial direction, respectively, and the thickness direction of the display device 10 is referred to as a Z axial direction, in some cases.

As illustrated in FIG. 3, the display device 10 according to the present embodiment has a configuration in which a plurality of LED packages 100 is two-dimensionally disposed in a matrix of rows and columns at equal intervals. As illustrated in FIG. 5, the plurality of LED packages 100 is each connected to a common substrate 11 of the display device 10 through a connection layer T such as solder or a conductive bonding film. Note that one LED package 100 corresponds to one pixel in the present embodiment, but a configuration in which an assembly of a plurality of LED packages 100 corresponds to one pixel is applicable. Furthermore, the LED packages 100 may be disposed in a two-dimensional arrangement referred to as a delta type. The number of LED packages 100 included in the display device 10 and the interval between the LED packages 100 may be appropriate values.

As illustrated in FIG. 4, each LED package 100 includes, for example, three LED chips provided in the Y axial direction. For example, a red (R) LED chip 101R, a green (G) LED chip 101G, and a blue (B) LED chip 101B are provided in the Y axial direction. Note that the LED chips are referred to as LED chips 101 as appropriate in a case where they do not need to be individually distinguished.

The thickness of each LED package 100 (length in the Z axial direction) is, for example, 30 μm or smaller and the thickness of each LED chip 101 is 10 μm or smaller.

Each LED package 100 includes a substrate 102. The substrate 102 includes poly chlorinated biphenyl (PCB) sapphire, glass, or the like. The substrate 102 is provided with the red LED chip 101R, the green LED chip 101G, and the blue LED chip 101B described above.

Each LED chip 101 is covered (molded) by a transparent resin part 103. The transparent resin part 103 has, for example, a refractive index approximately equal to or larger than 1.2 and equal to or smaller than 1.8 and contains no scatterer that scatters light. The LED package 100 covered by the transparent resin part 103 has a substantially rectangular parallelepiped shape as a whole. When the LED chips 101R, 101G, and 101B emit light as appropriate in accordance with a video signal, the emitted light is visually recognized by the user through the transparent resin part 103. Note that the refractive index described above is measured by a critical angle method. Measurement wavelengths are the wavelengths of light emitted from the LED chips 101R, 101G, and 101B.

As illustrated in FIG. 5, the LED chip 101R is connected through a connection layer TR such as solder or a conductive bonding film. Similarly, the LED chip 101G is connected through a connection layer TG such as solder or a conductive bonding film, and the LED chip 101B is connected through a connection layer TB such as solder or a conductive bonding film.

The connection layer TR is connected to a drive circuit (not illustrated) incorporated in the common substrate 11 or the like through a wire and a conductive layer that are not illustrated and the connection layer T. Accordingly, drive control by the drive circuit is performed on the LED chip 101R, and the LED chip 101R emits light or turns off in accordance with the drive control. Similarly, the connection layer TG is connected to a drive circuit (not illustrated) incorporated in the common substrate 11 or the like through a wire and a conductive layer that are not illustrated and the connection layer T. Accordingly, drive control by the drive circuit is performed on the LED chip 101G, and the LED chip 101G emits light or turns off in accordance with the drive control. Furthermore, the connection layer TB is connected to a drive circuit (not illustrated) incorporated in the common substrate 11 or the like through a wire and a conductive layer that are not illustrated and the connection layer T. Accordingly, drive control by the drive circuit is performed on the LED chip 101B, and the LED chip 101B emits light or turns off in accordance with the drive control.

Each LED chip 101 is formed by using, for example, a transfer technology as described below. First, semiconductor layers that constitute the LED chip 101 are sequentially epitaxially grown on a growth substrate and then each semiconductor layer is shaped in a desired size. Subsequently, the shaped semiconductor layers are peeled off from the growth substrate (substrate including sapphire, glass, or the like) and transferred onto another substrate (substrate 102 in the present embodiment), and accordingly, the LED chip 101 is formed. The transfer is performed, for example, by using a physical pickup scheme, a laser peeling method, or the like. For example, the LED chips 101R, 101G, and 101B are disposed at a predetermined pitch on the substrate 2 after the transfer. Accordingly, the LED chip 101 has a smaller thickness.

[Structure that Suppresses End-Surface Vignetting]

Next, a configuration that suppresses the end-surface vignetting due to an end surface 104 (refer to FIG. 5) of each LED package 100 will be described below. Deterioration in image quality of the display device 10 occurs when deterioration in image quality due to the end-surface vignetting is sensitively recognized. Thus, in the present embodiment, the amount of color shift due to the end-surface vignetting was sensitively evaluated, the amount of vignetting was converted into Δu‘v’, and criteria were set for each value. The criteria are as follows.
Color shift is hardly sensed: Δu‘v’<0.005
Color shift is sensed but allowable: Δu‘v’=0.005 to 0.010
Deterioration of image state (image quality) is sensed: Δu‘v’=0.010 to 0.020
Image state is not allowable: Δu‘v’>0.020

Furthermore, RGB intensities for criteria of the chromaticity point were quantified. Specifically, it was quantified what % of vignetting was needed to cause the range of each Δu‘v’ only by RGB shift of the corresponding color.

In the present example, the chromaticity of each of RGB was set as described below.
Red: (x, y)=(0.7103, 0.2896), (u‘v’)=(0.5621, 0.5156)
Green: (x, y)=(0.1939, 0.7262), (u‘v’)=(0.0685, 0.5770)
Blue: (x, y)=(0.1403, 0.0439), (u‘v’)=(0.1729, 0.1217)

Furthermore, white chromaticity point as an adjustment target was set as described below. This corresponds to D93 in color temperature.
White: (x, y)=(0.283, 0.297), (u‘v’)=(0.1887, 0.4456)

Note that (x, y) is based on an xy chromaticity diagram (CIE 1931) and (u‘v’) is based on a UCS chromaticity diagram (CIE 1976). The value x is converted into u′ by Expression (2) below and the value y is converted into v′ by Expression (3) below.

u′=4x/(−2x+12y+3) Expression (2)

v′=9y/(−2x+12y+3) Expression (3)

With the above-described setting, it was quantified what degree of vignetting in each color among RGB was present when the above-described chromaticity difference was obtained.
Corresponds to Δu‘v’=0.005 R=7.0%/G=5.2%/B=5.9%
Corresponds to Δu‘v’=0.010 R=14.3%/G=10.8%/B=12.0%
Corresponds to Δu‘v’=0.020 R=29.5%/G=23.0%/B=24.9%

Note that which of the three LED chips is disposed at a position closest to the end surface 104 depends on the design of the LED package 100. Thus, in the present embodiment, the quantification was performed for vignetting of green for which conditions of light quantity decrease due to vignetting were most severe.

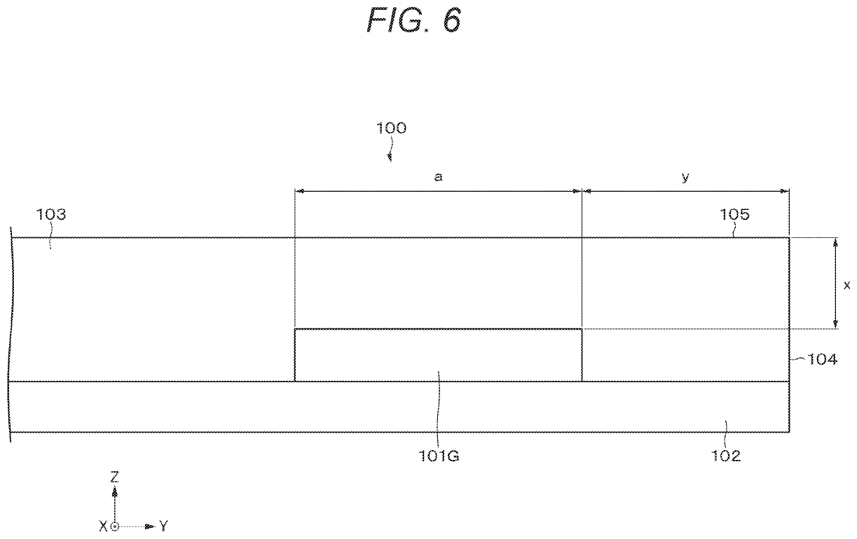

The amount of change of the chromaticity point due to vignetting depends on a ratio relative to the light quantity of the entire LED chip. Thus, three parameters illustrated in FIG. 6 are defined as a dimension ratio of a non-vignetting structure for each of the above-described criteria.

Specifically,
Refractive index of the transparent resin part 103: λm

Dimension (length in a direction substantially orthogonal to the end surface 104) of the LED chip 101G: a (μm)

Surface distance from a surface of the LED chip 101G to a surface 105 of the LED package 100: x (μm)

End surface distance from an end surface of the LED chip 101G on the end surface 104 side to the end surface 104 of the LED package 100: y (μm)

The value of each variable is adjusted to determine a range in which light quantity decrease due to the end-surface vignetting is allowable.

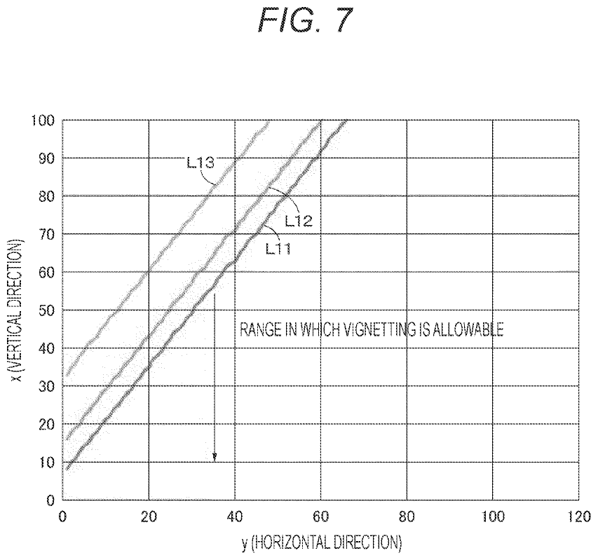

For example, in a case where the refractive index λm=1.5 and a=100 μm are satisfied, vignetting with the relation between x and y under a condition illustrated in FIG. 7 is sensitively allowable in the view angle range of 60°. Note that, in FIG. 7, line L11 is an approximate straight line corresponding to Δu‘v’=0.005, line L12 is an approximate straight line corresponding to Δu‘v’=0.010, and line L13 is an approximate straight line corresponding to Δu‘v’=0.020.

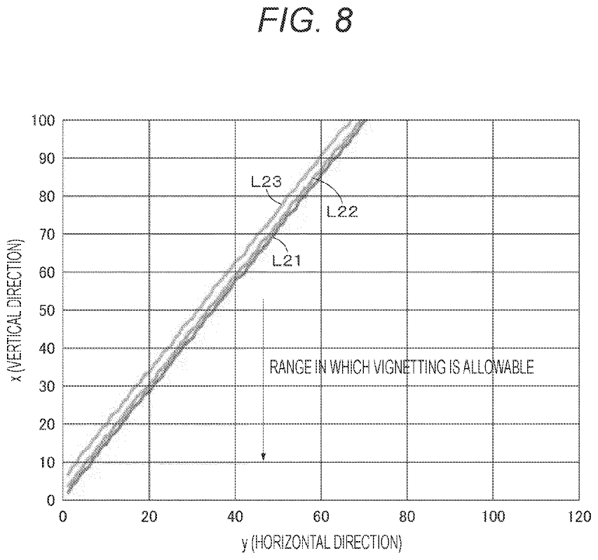

For example, in a case where the refractive index λm=1.5 and a=20 μm are satisfied, vignetting with the relation between x and y under a condition illustrated in FIG. 8 is sensitively allowable in the view angle range of 60°. Note that, in FIG. 8, line L21 is an approximate straight line corresponding to Δu‘v’=0.005, line L22 is an approximate straight line corresponding to Δu‘v’=0.010, and line L23 is an approximate straight line corresponding to Δu‘v’=0.020.

Conditions that the respective criteria are satisfied are generalized as follows:
(1) When the relation of Expression (4) below is satisfied, Δu‘v’<0.005 is obtained and color shift is hardly sensed.

y<(1.44λm−0.76)×x+(0.08λm−0.04)×a−0.02λm−0.47 Expression (4)
(2) When the relations of Expressions (5) and (6) below are satisfied, 0.005<Δu‘v’<0.010 is obtained and color shift is sensed but at a sensitively allowable level.

y≥(1.44λm−0.76)×x+(0.08λm−0.04)×a−0.02λm−0.47 Expression (5)

y<(1.44λm−0.76)×x+(0.15λm−0.08)×a−0.06λm−0.61 Expression (6)
(3) When the relations of Expressions (7) and (8) below are satisfied, 0.010≤Δu‘v’<0.020 is obtained and color shift is sensed at such a level that image state deterioration is sensitively sensed.

y≥(1.44λm−0.76)×x+(0.15λm−0.08)×a−0.06λm−0.61 Expression (7)

y<(1.44λm−0.76)×x+(0.33λm−0.18)×a−0.03λm−0.45 Expression (8)
(4) When the relation of Expression (9) below is satisfied, 0.020≤Δu‘v’ is obtained and image state deterioration is at a non-allowable level.

y≥(1.44λm−0.76)×x+(0.33λm−0.18)×a−0.03λm−0.45 Expression (9)

As described above, deterioration in image quality due to the end-surface vignetting can be suppressed when the LED package 100 is configured such that Expression (4) or Expressions (5) and (6) are satisfied. The relation of Expression (4) is preferably satisfied from a viewpoint of image quality but a configuration with which Expression (4) is not satisfied but Expressions (5) and (6) are satisfied is applicable.

### Effects Obtained by Present Embodiment

According to the present embodiment, as described above, it is possible to suppress deterioration in image quality due to the end-surface vignetting by applying a configuration that satisfies predetermined conditions to each LED package 100.

The end-surface vignetting does not need to be considered when a scatterer that scatters light is contained in the transparent resin part. However, the use of the scatterer leads to manufacturing cost increase and the like. According to the present embodiment, deterioration in image quality due to the end-surface vignetting can be suppressed without using the scatterer, and thus the process of manufacturing the LED package can be simplified and manufacturing cost can be reduced.

### Modification Examples

Although the embodiment of the present disclosure has been described above, the present disclosure is not limited to the above-described embodiment, and various modifications can be made without departing from the gist of the present disclosure.

The configuration in which each LED package includes the three LED chips is described above in the embodiment, but a configuration in which each LED package includes two LED chips or four or more LED chips is applicable. Furthermore, the disposition positions of the LED chips are changeable as appropriate. For example, the green LED chip or the red LED chip may be disposed at a position close to an end surface. Moreover, the relation between an LED chip and an end surface on one end part side is described above in the embodiment, but setting with which the conditions described above in the embodiment are satisfied is preferably performed on the other end part side as well.

Furthermore, the items described in each of the embodiments and the modification examples can be combined as appropriate. Furthermore, the contents of the present disclosure are not to be construed as being limited by the effects exemplified in the present specification. Moreover, the configurations, methods, steps, shapes, materials, numerical values, and the like described in the above-described embodiment and modification examples thereof are merely examples, and different configurations, methods, steps, shapes, materials, numerical values, and the like may be used as necessary.

Furthermore, the present disclosure can also adopt the following configurations.

(1)

A light emitting device including:
at least two light emitting elements provided on a substrate; and
a transparent resin part provided so as to cover the light emitting elements, in which
in a sectional view, when the size of the width of the light emitting element positioned at an end part is a (μm), a surface distance between the light emitting element and a surface of the transparent resin part is x (μm), an end surface distance between the light emitting element and an end surface of the transparent resin part closest to the light emitting element is y (μm), and the refractive index of the transparent resin part is λm, an expression (1) below or expressions (2) and (3) below are satisfied.

y<(1.44λm−0.76)×x+(0.08λm−0.04)×a−0.02λm−0.47 (Expression 1)

y<(1.44λm−0.76)×x+(0.08λm−0.04)×a−0.02λm−0.47 (Expression 2)

y<(1.44λm−0.76)×x+(0.15λm−0.08)×a−0.06λm−0.61 (Expression 3)

(2)

The light emitting device according to (1), in which
the expression (1) is satisfied and the expressions (2) and (3) are not satisfied.

(3)

The light emitting device according to (1), in which
the (1) is not satisfied and the expressions (2) and (3) are satisfied.

(4)

The light emitting device according to any one of (1) to (3), in which
the refractive index λm is equal to or larger than 1.2 and equal to or smaller than 1.8.

(5)

The light emitting device according to any one of (1) to (4), in which
a thickness of the light emitting device in the sectional view is 30 μm or smaller.

(6)

The light emitting device according to (5), in which
the thickness of each of the light emitting elements in the sectional view is 10 μm or smaller.

(7)

The light emitting device according to any one of (1) to (6), in which
the light emitting element positioned at the end part is a light emitting element configured to emit light in green.

(8)

The light emitting device according to any one of (1) to (7), in which
the light emitting elements include three light emitting elements.

(9)

The light emitting device according to (8), in which
the three light emitting elements are a first light emitting element configured to emit light in red, a second light emitting element configured to emit light in green, and a third light emitting element configured to emit light in blue.

(10)

The light emitting device according to any one of (1) to (9), in which
the light emitting elements are each an element peeled off from a growth substrate.

(11)

The light emitting device according to any one of (1) to (10), in which
the transparent resin part contains no scatterer that scatters light.

(12)

A display device including the light emitting device according to any one of (1) to (11).

### REFERENCE SIGNS LIST

10 Display device
100 LED package
101R, 101G, 101B LED chip
102 Substrate
103 Transparent resin part
104 End surface

1. A light emitting device comprising:
at least two light emitting elements provided on a substrate; and
a transparent resin part provided so as to cover the light emitting elements, wherein
in a sectional view, when a size of a width of the light emitting element positioned at an end part is a (μm), a surface distance between the light emitting element and a surface of the transparent resin part is x (μm), an end surface distance between the light emitting element and an end surface of the transparent resin part closest to the light emitting element is y (μm), and a refractive index of the transparent resin part is λm, an expression (1) below or expressions (2) and (3) below are satisfied:
y<(1.44λm−0.76)×x+(0.08λm−0.04)×a−0.02λm−0.47 (Expression 1)
y<(1.44λm−0.76)×x+(0.08λm−0.04)×a−0.02λm−0.47 (Expression 2)
y<(1.44λm−0.76)×x+(0.15λm−0.08)×a−0.06λm−0.61 (Expression 3)

2. The light emitting device according to claim 1, wherein
the expression (1) is satisfied and the expressions (2) and (3) are not satisfied.

3. The light emitting device according to claim 1, wherein
the (1) is not satisfied and the expressions (2) and (3) are satisfied.

4. The light emitting device according to claim 1, wherein
the refractive index λm is equal to or larger than 1.2 and equal to or smaller than 1.8.

5. The light emitting device according to claim 1, wherein
a thickness of the light emitting device in the sectional view is 30 μm or smaller.

6. The light emitting device according to claim 5, wherein
a thickness of each of the light emitting elements in the sectional view is 10 μm or smaller.

7. The light emitting device according to claim 1, wherein
the light emitting element positioned at the end part is a light emitting element configured to emit light in green.

8. The light emitting device according to claim 1, wherein
the light emitting elements include three light emitting elements.

9. The light emitting device according to claim 8, wherein
the three light emitting elements are a first light emitting element configured to emit light in red, a second light emitting element configured to emit light in green, and a third light emitting element configured to emit light in blue.

10. The light emitting device according to claim 1, wherein
the light emitting elements are each an element peeled off from a growth substrate.

11. The light emitting device according to claim 1, wherein
the transparent resin part contains no scatterer that scatters light.

12. A display device comprising the light emitting device according to claim 1.
